(19) United States
(12) Patent Application Publication
(10) Pub. No.: US 2026/0229470 A1
(43) Pub. Date: Aug. 6, 2026

(54) METHOD OF OPERATING PLASMA PROCESSING APPARATUS AND PLASMA PROCESSING APPARATUS

(71) Applicant: Tokyo Electron Limited, ,Tokyo (JP)

(72) Inventors: Kenichi KOTE, Nirasaki City (JP); Mitsutoshi ASHIDA, Nirasaki City (JP)

(21) Appl. No.: 19/457,523

(22) Filed: Jan. 23, 2026

(30) Foreign Application Priority Data
Feb. 6, 2025 (JP) 2025-018519

(51) Int. Cl. H01J 37/32; C23C 16/34; C23C 16/52

(52) U.S. Cl. CPC H01J 37/3299; C23C 16/345; C23C 16/52; H01J 37/32449; H01J 2237/332

(57) ABSTRACT

A method of operating a plasma processing apparatus includes: executing a first plasma process which simulates a plasma processing of a product substrate; executing a second plasma process with a higher electron temperature and a higher electron density than an electron temperature and an electron density in the first plasma process; and measuring, by a probe device, data representing a state of plasma generated during the execution of at least one of the first plasma process or the second plasma process and determining whether the plasma processing of the product substrate can be started based on the measured data.

### CROSS-REFERENCE TO RELATED APPLICATION

This application is based upon and claims the benefit of priority from Japanese Patent Application No. 2025-018519, filed on February 6, 2025, the entire contents of which are incorporated herein by reference.

### TECHNICAL FIELD

The present disclosure relates to a method of operating a plasma processing apparatus and the plasma processing apparatus.

### BACKGROUND

Patent Document 1 discloses a technique of performing a pre-coating process before performing a film formation process inside a processing container.

### Prior Art Document

### Patent Document

Patent Document 1: Japanese Laid-Open Publication No. 2006-294816

### SUMMARY

According to one embodiment of the present disclosure, a method of operating a plasma processing apparatus includes: executing a first plasma process which simulates a plasma processing of a product substrate; executing a second plasma process with a higher electron temperature and a higher electron density than an electron temperature and an electron density in the first plasma process; and measuring, by a probe device, data representing a state of plasma generated during the execution of at least one of the first plasma process or the second plasma process and determining whether the plasma processing of the product substrate can be started based on the measured data.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing a plasma processing apparatus according to an embodiment.

FIG. 2 is a diagram showing an example of a functional configuration of a measurement system and a control device according to an embodiment.

FIG. 3 is a flowchart showing a method of operating a plasma processing apparatus according to an embodiment.

FIG. 4 is a flowchart showing an example of a conditioning process.

FIG. 5 is a flowchart showing an example of a dummy process.

FIG. 6 is a schematic cross-sectional view showing a ceiling plate on which a seasoning process has not been performed.

FIG. 7 is a schematic cross-sectional view showing a ceiling plate on which a seasoning process has been performed.

FIG. 8 is a diagram showing a relationship between a time of a conditioning process and the number of particles.

FIG. 9 is a diagram 1 showing a variation in a current value detected by a probe device.

FIG. 10 is a diagram 2 showing a variation in a current value detected by the probe device.

FIG. 11 is a diagram 3 showing a variation in a current value detected by the probe device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limitative exemplary embodiments of the present disclosure will be described with reference to the accompanying drawings. In all the attached drawings, the same or corresponding members or components will be denoted by the same or corresponding reference numerals, and redundant explanations thereof will be omitted.

### Plasma Processing Apparatus

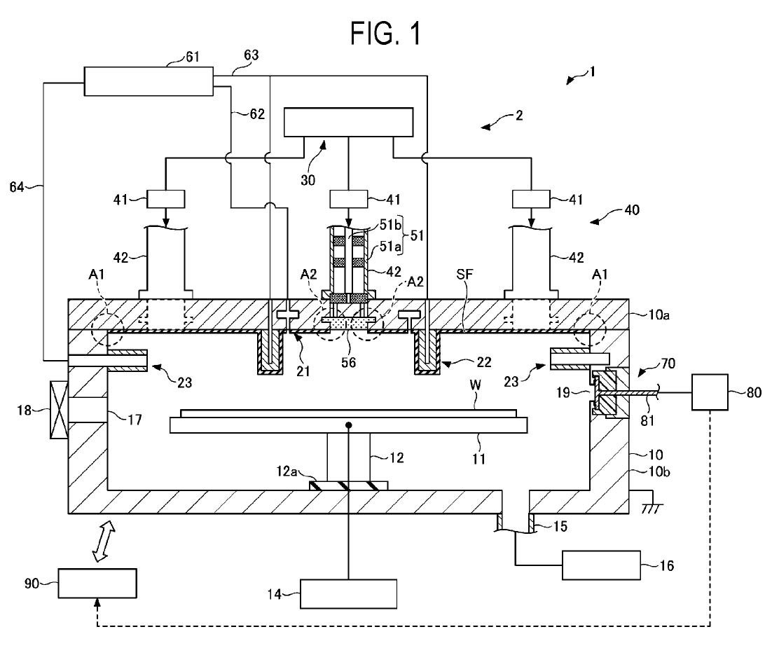

A plasma processing apparatus 1 according to an embodiment will now be described with reference to FIG. 1. FIG. 1 is a schematic cross-sectional view showing the plasma processing apparatus 1 according to the embodiment.

The plasma processing apparatus 1 includes a processing container 10 and a plasma source 2. The processing container 10 has a substantially cylindrical shape. The processing container 10 is formed of a metallic material such as aluminum or the like, which is airtightly configured. The processing container 10 is grounded. The plasma source 2 introduces microwaves (electromagnetic waves) of predetermined power into the processing container 10 to form surface wave plasma. A ceiling plate 10a of the processing container 10 is configured such that dielectric members (hereinafter, also referred to as dielectric windows 56) of a plurality of microwave radiators 42 are inserted into a metallic main body. Thereby, the plasma source 2 is configured to introduce the microwaves into the processing container 10 via a plurality of dielectric windows 56 of the ceiling plate 10a.

The plasma processing apparatus 1 includes a control device 90. The control device 90 is an electronic circuit such as a central processing unit (CPU), a field programmable gate array (FPGA), or an application specific integrated circuit (ASIC). The control device 90 executes various control operations described herein by executing instruction code stored in a memory or by being designed as a circuit for a special purpose.

In the processing container 10, a stage 11 is supported at a center of a bottom portion of the processing container 10 by a tubular support member 12 via an insulating member 12a. The stage 11 horizontally supports a substrate W. A material constituting the stage 11 and the support member 12 is, for example, a metal such as aluminum having an alumite treated (anodically oxidized) surface or an insulating material (ceramic, or the like) having a radio-frequency electrode therein.

The stage 11 is provided with a temperature controller, a gas channel for supplying a heat transfer gas to a back surface of the substrate W, and pins that move up and down to transfer the substrate W. The stage 11 may also be provided with an electrostatic chuck for electrostatically attracting the substrate W.

A direct current (DC) power supply 14 is connected to the stage 11. By supplying a DC voltage from the DC power supply 14 to the stage 11, ions in plasma are drawn into the substrate W, which contributes a film quality improvement and in-plane uniformity of a substrate processing. Instead of the DC power supply 14, a radio-frequency power supply may be connected. Alternatively, the DC power supply 14 or the radio-frequency power supply may not be connected.

An exhaust pipe 15 is connected to the bottom portion of the processing container 10. An exhaust device 16 including a vacuum pump is connected to the exhaust pipe 15. By operating the exhaust device 16, it is possible to exhaust an interior of the processing container 10, and reduce a pressure inside the processing container 10 to a predetermined level. A side wall portion 10b of the processing container 10 is provided with a loading/unloading port 17 for loading and unloading the substrate W and a gate valve 18 for opening and closing the loading/unloading port 17.

The plasma processing apparatus 1 includes a first gas shower portion 21, a second gas shower portion 22, and a third gas shower portion 23. The first gas shower portion 21 discharges a predetermined gas from the ceiling plate 10a of the processing container 10 into the processing container 10. The second gas shower portion 22 introduces a gas from a position between the ceiling plate 10a and the stage 11. The third gas shower portion 23 introduces a gas from a position between the ceiling plate 10a and the stage 11 in the processing container 10 and is located farther outward than the second gas shower portion 22.

Although the first gas shower portion 21 and the second gas shower portion 22 are shown in FIG. 1 at positions offset in the radial direction for convenience, in practice, the first gas shower portion 21 and the second gas shower portion 22 are arranged alternately on a same circle. The first gas shower portion 21 is provided in the ceiling plate 10a of the processing container 10 and supplies a gas, which is carried via a gas line 62 from a gas supply 61, from a first position. The second gas shower portion 22 is provided in the ceiling plate 10a of the processing container 10 and supplies a gas, which is carried via a gas line 63 from the gas supply 61, from a second position lower than the first position. The third gas shower portion 23 is provided in the side wall portion 10b of the processing container 10 and supplies a gas, which is carried via a gas line 64 from the gas supply 61, from a third position lower than the first position.

The plasma source 2 includes a microwave output 30 that distributes microwaves into multiple paths and outputs the microwaves, and a microwave transmitter 40 that transmits the microwaves output from the microwave output 30.

The microwave output 30 includes a microwave power supply, a microwave oscillator, an amplifier, and a distributor. The microwave power supply provides power to the microwave oscillator. The microwave oscillator oscillates microwaves at a predetermined frequency (e.g., 860 MHz) using, for example, a phase locked loop (PLL) oscillation. The amplifier amplifies the oscillated microwave. The distributor distributes the microwaves amplified by the amplifier while maintaining an impedance matching between an input and an output so that a loss of the microwaves is minimized as much as possible. As a frequency of the microwave, various frequencies in a range of 700 MHz to 3 GHz, such as 915 MHz, may be used in addition to 860 MHz.

The microwave transmitter 40 includes a plurality of amplifiers 41 and the plurality of microwave radiators 42 that correspond to the amplifiers 41. For example, a total of seven microwave radiators 42 are arranged so that one is disposed at a center of the ceiling plate 10a, and six others are disposed at equal intervals on a circumference centered on the central one. In this example, the microwave radiators 42 are arranged so that a distance between the central microwave radiator 42 and each of the outer peripheral microwave radiators 42 is equal to a distance between adjacent outer peripheral microwave radiators 42.

Each amplifier 41 amplifies the microwaves distributed by the distributor and guides the amplified microwaves to the corresponding microwave radiator 42. The microwave radiator 42 includes a coaxial tube 51. The coaxial tube 51 has a coaxial microwave transmission path composed of a cylindrical outer conductor 51a and a rod-shaped inner conductor 51b which is provided at a center of the outer conductor 51a. The microwave radiator 42 includes a power feeding antenna (not shown) which feeds the microwaves amplified by the amplifier 41 to the coaxial tube 51. The microwave radiator 42 further includes a tuner that matches a load impedance to a characteristic impedance of the microwave power supply and an antenna that radiates the microwaves from the coaxial tube 51 into the processing container 10.

The antenna is provided at a lower end portion of the coaxial tube 51 and is inserted into a metallic portion of the ceiling plate 10a of the processing container 10. The antenna includes a dielectric window 56, and surface wave plasma is generated directly below the dielectric window 56 inside the processing container 10 by the microwaves transmitted through the dielectric window 56.

One plasma source 2 (dielectric window 56) is disposed at the center of a ceiling portion, and six plasma sources 2 (dielectric windows 56) are disposed in an outer peripheral portion of the ceiling portion. Each of the plasma sources 2 (dielectric windows 56) is capable of independently controlling microwave power supplied from the corresponding plasma source 2. The microwave power supplied from the plasma source 2 (dielectric window 56) on the outer peripheral portion may be higher than, lower than, or the same as the microwave power supplied from the plasma source 2 in the central portion.

A surface of the ceiling plate 10a inside the processing container 10 is covered with a thermal sprayed film SF. The thermal sprayed film SF is formed of a material having a plasma resistance. The material having the plasma resistance may be a ceramic material such as yttria (Y₂O₃). The thermal sprayed film SF protects the surface of the ceiling plate 10a inside the processing container 10 from plasma during a plasma processing and reduces a generation of particles caused by a metallic material such as aluminum which constitutes the ceiling plate 10a. A surface of the second gas shower portion 22 is also covered with the thermal sprayed film SF, similarly to the surface of the ceiling plate 10a inside the processing container 10.

When the plasma processing is performed in the plasma processing apparatus 1, the substrate W is first loaded into the processing container 10 via the loading/unloading port 17 while being held on a transfer arm (not shown). When the substrate W is transferred above the stage 11, the substrate W is moved from the transfer arm onto the pins and is then placed on the stage 11 as the pins descend. After the substrate W is loaded, the gate valve 18 is closed. The internal pressure of the processing container 10 is maintained at a predetermined vacuum level by the exhaust device 16. A process gas is introduced into the processing container 10 from at least one of the first gas shower portion 21, the second gas shower portion 22, or the third gas shower portion 23. The microwaves radiated from the microwave radiator 42 propagate in a vicinity of a lower surface, which is the surface of the ceiling plate 10a. The process gas is excited by an electric field of surface wave microwaves, and the plasma processing is performed on the substrate W by the surface wave plasma generated in a plasma generation space below the ceiling plate 10a inside the processing container 10.

The surface of the ceiling plate 10a inside the processing container 10 is covered with the thermal sprayed film SF. However, it is difficult to completely cover all areas including fine end portions and the like. For example, at an end portion (an area A1 in FIG. 1) of the ceiling plate 10a inside the processing container 10, at a boundary portion (an area A2 in FIG. 1) between the ceiling plate 10a and the dielectric window 56, and the like, an exposed portion of the metallic material not covered with the thermal sprayed film SF may exist. During the plasma processing, there are cases in which the particles originating from a metallic material such as aluminum are generated, starting from the exposed portion. In particular, under conditions in which the ceiling plate 10a is new and the plasma processing is performed using high-power microwaves, particles are likely to occur.

As a method of reducing a generation of particles, there is, for example, a method of stabilizing a surface inside the processing container 10 by alternately repeating a pre-coating process and a cleaning process. In this method, it takes a long time to stabilize the surface inside the processing container 10.

Hereinafter, a method of operating the plasma processing apparatus 1, which can stabilize the surface inside the processing container 10 in a short time and can also determine a stabilization of the surface inside the processing container 10 in a short time, will be described.

### Probe Device

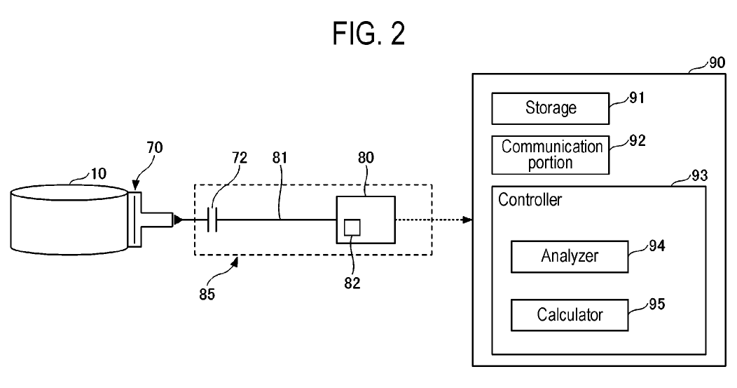

A probe device 70 will now be described with reference to FIGS. 1 and 2. FIG. 2 is a diagram showing an example of a functional configuration of a measurement system and the control device 90 according to an embodiment.

As shown in FIG. 1, an opening 19 is formed below the third gas shower portion 23 in the side wall portion 10b of the processing container 10. The probe device 70 is installed in the opening 19 via a sealing member (not shown) that seals a space between a vacuum space and an atmospheric space. A gap of a predetermined width is formed between a front end surface of the probe device 70 and a back surface of a wall of the processing container 10 in a vicinity of the opening 19. The gap is designed to be wide enough that the probe device 70 is not DC-connected to the wall of the processing container 10 and narrow enough that plasma or a gas does not enter.

As shown in FIG. 2, the measurement system for measuring a plasma state includes the probe device 70 and a measurement circuit 85. The measurement circuit 85 includes a monitor device 80, a blocking capacitor 72, and a coaxial cable 81. The monitor device 80 is communicably connected to the control device 90.

The probe device 70 is connected to the monitor device 80 by the coaxial cable 81 from outside the plasma processing apparatus 1. The monitor device 80 includes a signal transmitter 82. The signal transmitter 82 outputs a signal of an alternating current (AC) voltage with a predetermined frequency to the coaxial cable 81. The signal of the AC voltage is transmitted to the coaxial cable 81, and the AC voltage is applied to the probe device 70. The blocking capacitor 72 is connected to the coaxial cable 81 to transmit the signal of the AC voltage to the probe device 70 and block a signal of a DC voltage. In this way, the monitor device 80 receives only the signal of the AC voltage from a plasma side.

The probe device 70 senses plasma generated inside the processing container 10. The monitor device 80 detects a current signal flowing toward the plasma via the probe device 70. The current signal flowing toward the plasma is transmitted from the monitor device 80 to the control device 90 and received by a communication portion 92 of the control device 90. A current value of the received signal is stored in a storage 91. An analyzer 94 of the control device 90 analyzes the current value of the received signal by fast Fourier transform (FFT). A calculator 95 of the control device 90 calculates at least one of a plasma electron temperature, a plasma ion density, or a plasma electron density based on the analyzed results. Accordingly, it is possible to accurately estimate the plasma state. A controller 93 of the control device 90 executes step S12 of the method of operating the plasma processing apparatus 1, which will be described later, based on the current value of the received signal. In this way, the plasma measurement system which measures the plasma state includes the probe device 70, the measurement circuit 85, and the control device 90 (controller 93).

In FIG. 1, the case has been described in which one probe device 70 is installed below the third gas shower portion 23 in the side wall portion 10b of the processing container 10. However, a position in which the probe device 70 is installed and the number of the probe devices 70 are not limited thereto. The position at which the probe device 70 is installed may be any position capable of sensing the plasma generated inside the processing container 10. For example, the probe device 70 may be installed above the third gas shower portion 23 in the side wall portion 10b of the processing container 10. The probe device 70 may be installed in the ceiling plate 10a of the processing container 10. Further, the probe device 70 may be installed on the stage 11. A plurality of probe devices 70 may be provided. For example, the plurality of probe devices 70 may be provided at intervals along the circumferential direction of the processing container 10. The probe devices 70 may be installed at two or more locations among the ceiling plate 10a of the processing container 10, the side wall portion 10b of the processing container 10, and the stage 11.

### Method of Operating Plasma Processing Apparatus

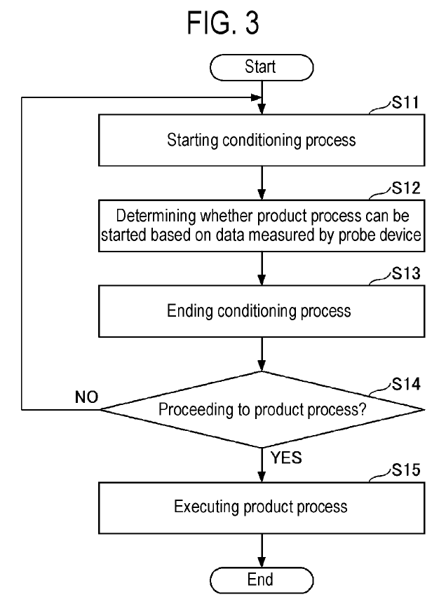

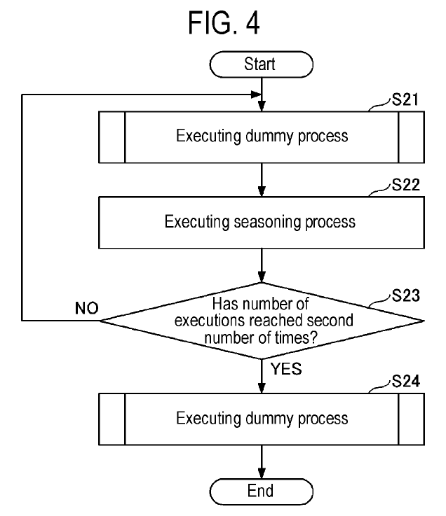

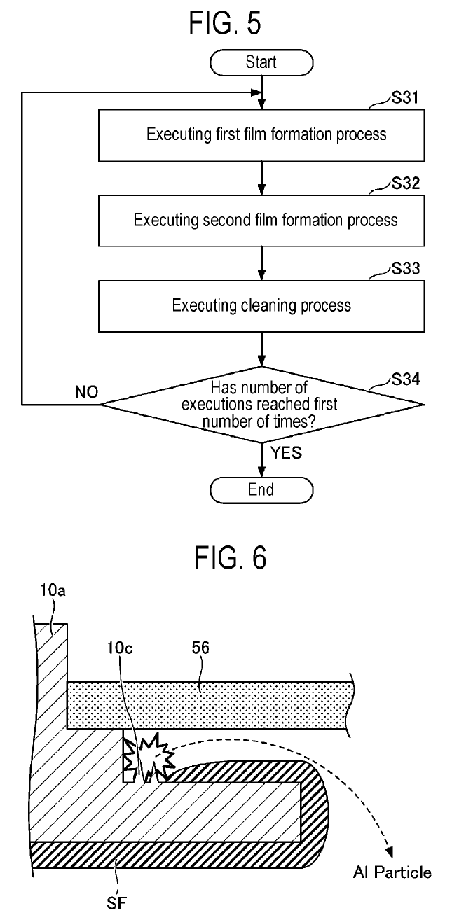

The method of operating the plasma processing apparatus 1 according to an embodiment will now be described with reference to FIGS. 3 to 5. FIG. 3 is a flowchart showing an example of the method of operating the plasma processing apparatus 1 according to the embodiment. FIG. 4 is a flowchart showing an example of a conditioning process. FIG. 5 is a flowchart showing an example of a dummy process.

The method of operating the plasma processing apparatus 1 according to the embodiment is executed, for example, after a component in contact with plasma has been replaced and before a plasma processing for a product substrate (hereinafter, referred to as a "product process") is performed inside the processing container 10. The component in contact with the plasma is, for example, the ceiling plate 10a of the processing container 10. The component in contact with the plasma may be a member constituting the first gas shower portion 21, a member constituting the second gas shower portion 22, or a member constituting the third gas shower portion 23. The product process is a process in which, for example, a silicon nitride film is formed on the product substrate by an atomic layer deposition (ALD), a chemical vapor deposition (CVD), or the like using plasma.

The method of operating the plasma processing apparatus 1 according to the embodiment includes steps S11 to S15 shown in FIG. 3.

In step S11, the control device 90 controls the plasma processing apparatus 1 so as to start the conditioning process. The conditioning process includes steps S21 to S24 shown in FIG. 4.

In step S21, the control device 90 controls the plasma processing apparatus 1 so as to execute the dummy process. The dummy process includes steps S31 to S34 shown in FIG. 5.

In step S31, the control device 90 executes a first film formation process of supplying microwaves of a first power into the processing container 10 and forming a first film on a surface of the processing container 10 by plasma generated from a first film formation gas using the microwaves of the first power. The purpose of the first film formation process is to promote adhesion between a sidewall of the processing container 10 and a silicon nitride film, using conditions under which particles caused by insufficient adhesion of the silicon nitride film are unlikely to occur. Therefore, the conditions of the first film formation process differ from conditions of the product process. The first film formation gas may include a silicon-containing gas and a nitrogen-containing gas. In this case, it is possible to form the silicon nitride film as the first film. The silicon-containing gas may be supplied from at least one of the second gas shower portion 22 or the third gas shower portion 23. By supplying the silicon-containing gas from at least one of the second position or the third position lower than the first position of the first gas shower portion 21, it is possible to reduce excessive dissociation of the silicon-containing gas. The silicon-containing gas is, for example, a monosilane gas. Alternatively, the silicon-containing gas may be a disilane gas. The nitrogen-containing gas may be supplied from at least one of the first gas shower portion 21, the second gas shower portion 22, or the third gas shower portion 23. The nitrogen-containing gas is, for example, an ammonia gas. Alternatively, the nitrogen-containing gas may be a nitrogen gas.

In step S32, the control device 90 executes a second film formation process of supplying microwaves of a second power into the processing container 10 and forming a second film on the surface of the processing container 10 by plasma generated from a second film formation gas using the microwaves of the second power. The second film formation process is an example of a first plasma process. The purpose of the second film formation process is to stabilize the silicon nitride film formed on the product substrate. Therefore, conditions of the second film formation process simulate the conditions of the product process. The conditions of the second film formation process are, for example, the same as the conditions of the product process. The second film formation gas may include a silicon-containing gas and a nitrogen-containing gas. In this case, it is possible to form a silicon nitride film as the second film. The silicon-containing gas may be supplied from at least one of the second gas shower portion 22 or the third gas shower portion 23. By supplying the silicon-containing gas from at least one of the second position or the third position lower than the first position of the first gas shower portion 21, it is possible to reduce excessive dissociation of the silicon-containing gas. The silicon-containing gas is, for example, a monosilane gas. Alternatively, the silicon-containing gas may be a disilane gas. The nitrogen-containing gas may be supplied from at least one of the first gas shower portion 21, the second gas shower portion 22, or the third gas shower portion 23. The nitrogen-containing gas is, for example, an ammonia gas. Alternatively, the nitrogen-containing gas may be a nitrogen gas. The second film formation process of step S32 may be repeated multiple times.

In step S33, the control device 90 executes the cleaning process of supplying microwaves of a third power into the processing container 10 and cleaning the interior of the processing container 10 by plasma generated from a cleaning gas using the microwaves of the third power. The cleaning gas includes a halogen-containing gas. The halogen-containing gas may be supplied from the first gas shower portion 21. By supplying the halogen-containing gas from the first gas shower portion 21, it is possible to promote dissociation of the halogen-containing gas. The halogen-containing gas is, for example, a nitrogen trifluoride gas.

In step S34, the control device 90 determines whether steps S31 to S33 have been performed a first number of times. When the number of executions has not reached the first number of times (NO in step S34), the control device 90 performs steps S31 to S33 again. When the number of executions has reached the first number of times (YES in step S34), the control device 90 terminates the dummy process and proceeds to step S22. In this way, the control device 90 controls the plasma processing apparatus 1 so as to repeat steps S31 to S33 until the number of executions reaches the first number of times. The first number of times may be, for example, two or more. Alternatively, the first number of times may be one.

In step S22, the control device 90 executes a seasoning process of supplying plasma generated from a seasoning gas into the processing container 10 using microwaves of a fourth power. The seasoning process is an example of a second plasma process. The seasoning process may be performed under conditions having a higher electron temperature and a higher electron density than the conditions in the product process. The seasoning gas includes a hydrogen-containing gas and an inert gas. The hydrogen-containing gas and the inert gas may be supplied from at least one of the first gas shower portion 21, the second gas shower portion 22, or the third gas shower portion 23. The hydrogen-containing gas is, for example, an ammonia gas. Alternatively, the hydrogen-containing gas may be a hydrogen gas. The inert gas is, for example, an argon gas. In this case, it is easy to obtain a high electron temperature and a high electron density. In addition, the inert gas may be a helium gas or a nitrogen gas. Alternatively, the seasoning gas may not include the inert gas.

In step S23, the control device 90 determines whether steps S21 and S22 have been performed a second number of times. When the number of executions has not reached the second number of times (NO in step S23), the control device 90 performs steps S21 and S22 again. When the number of executions has reached the second number of times (YES in step S23), the control device 90 proceeds to step S24. In this way, the control device 90 controls the plasma processing apparatus 1 so as to repeat steps S21 to S22 until the number of executions reaches the second number of times. The second number of times is, for example, two or more. Alternatively, the second number of times may be one.

In step S24, the control device 90 controls the plasma processing apparatus 1 so as to execute a dummy process. The dummy process in step S24 may be the same as the dummy process in step S21. After executing the dummy process in step S24, the control device 90 terminates the conditioning process (step S13).

Step S12 is performed between steps S11 and S13. In other words, step S12 is performed during the execution of the conditioning process.

In step S12, the control device 90 measures, by the probe device 70, first data representing a state of plasma generated during the execution of the second film formation process and determines whether the product process can be started based on the measured first data. The first data may be time-series data of a current signal detected by the probe device 70 when an AC voltage is applied to the probe device 70. There is a correlation between the time-series data of the current signal detected by the probe device 70 during the execution of the second film formation process and the number of particles adhering to a product substrate during the product process. Specifically, as the number of the particles adhering to the product substrate during the product process increases, a variation in the time-series data of the current signal detected by the probe device 70 during the second film formation process becomes larger. This is considered to be because as the number of the particles adhering to the product substrate during the product process increases, exposed portions of a metallic material, which serve as sources of particles originating from the metallic material, exist more inside the processing container 10, and because an abnormal discharge starting from the exposed portions occurs during the second film formation process. Therefore, by determining whether the product process can be started based on the time-series data detected by the probe device 70 during the execution of the second film formation process, it is possible to perform the product process while suppressing the generation of the particles.

For example, when the number of data values that fall outside a first range in a first period in the time-series data of the current signal, which is detected by the probe device 70 during the execution of the second film formation process, is equal to or less than a first threshold, the control device 90 determines that the product process can be started. Conversely, the control device 90 determines that the product process cannot be started when the number of data values that fall outside the first range in the first period in the time-series data of the current signal, which is detected by the probe device 70 during the execution of the second film formation process, exceeds the first threshold. The first period may be a period from a time when a predetermined time has elapsed after the start of the second film formation process to a time when the second film formation process ends. In other words, the first period may not include the predetermined time immediately after the start of the second film formation process. In this way, it is possible to eliminate an influence of a variation in a current signal that may occur immediately after plasma generation. The predetermined time is, for example, 1 second or more and 10 seconds or less. Alternatively, the first period may be a period from the start of the second film formation process to the end of the second film formation process. Further, the first range may be set through preliminary experiments or the like. The first range may be ± 20% of a median value of the time-series data of the current signal in the first period. Alternatively, the first range may use an average value instead of the median value. In other words, the first range may be ± 20% of the average value of the time-series data of the current signal in the first period. For example, when the median value of the time-series data of the current signal in the first period is 40 μA, the first range may be 40 μA ± 8 μA. The first threshold may also be set through preliminary experiments or the like. The first threshold may be 0 or more and 2 or less, for example, 1.

For example, the control device 90 may control the plasma processing apparatus 1 so as to repeatedly execute the second film formation process multiple times. In this case, the control device 90 may measure, by the probe device 70, first data indicating a state of plasma generated during repeated executions of the second film formation process and determine whether the product process can be started based on the measured first data. Specifically, the control device 90 first acquires time-series data of a current signal detected by the probe device 70 during each execution of the repeated second film formation process. Next, for each of multiple sets of the time-series data of the current signal, the control device 90 calculates the number of data values that fall outside the first range in the first period. Subsequently, when the total number of the calculated data values is equal to or less than the first threshold, the control device 90 determines that the product process can be started. In contrast, when the total number of the calculated data values exceeds the first threshold, the control device 90 determines that the product process cannot be started. The number of times the second film formation process is repeated may be 10 times or more and 100 times or less, for example, 25 times.

In step S12, the control device 90 may measure, by the probe device 70, second data representing a state of plasma generated during the execution of the seasoning process and determine whether the product process can be started based on the measured second data. The second data may be time-series data of a current signal detected by the probe device 70 when an AC voltage is applied to the probe device 70. There is a correlation between the time-series data of the current signal detected by the probe device 70 during the execution of the seasoning process and the number of the particles adhering to the product substrate during the product process. Specifically, as the number of the particles adhering to the product substrate during the product process increases, a variation in the time-series data of the current signal detected by the probe device 70 during the seasoning process becomes larger. This is considered to be because as the number of the particles adhering to the product substrate during the product process increases, exposed portions of a metallic material, which serve as the sources of the particles originating from the metallic material, exist more inside the processing container 10, and because the abnormal discharge starting from the exposed portions occurs during the seasoning process. Therefore, by determining whether the product process can be started based on the time-series data detected by the probe device 70 during the execution of the seasoning process, it is possible to perform the product process while suppressing the generation of the particles.

For example, when the number of data values that fall outside a second range in a second period in the time-series data of the current signal, which is detected by the probe device 70 during the execution of the seasoning process, is equal to or less than a second threshold, the control device 90 determines that the product process can be started. Conversely, the control device 90 determines that the product process cannot be started when the number of the data values that fall outside the second range in the second period in the time-series data of the current signal, which is detected by the probe device 70 during the seasoning process, exceeds the second threshold. The second period may be a period from a time when a predetermined time has elapsed after the start of the seasoning process to a time when the seasoning process ends. In other words, the second period may not include the predetermined time immediately after the start of the seasoning process. In this way, it is possible to eliminate the influence of the variation in the current signal that can occur immediately after plasma generation. The predetermined time is, for example, 1 second or more and 10 seconds or less. Alternatively, the second period may be a period from the start of the seasoning process to the end of the seasoning process. Further, the second range may be set through preliminary experiments or the like. The second range may be ± 20% of a median value of the time-series data of the current signal in the second period. Alternatively, the second range may use an average value instead of the median value. In other words, the second range may be ± 20% of the average value of the time-series data of the current signal in the second period. For example, when the median value of the time-series data of the current signal in the second period is 40 μA, the second range may be 40 μA ± 8 μA. The second threshold may also be set through preliminary experiments or the like. The second threshold may be 0 or more and 2 or less, for example, 1.

In step S12, the control device 90 may determine whether the product process can be started based on both the first data and the second data described above.

In step S14, the control device 90 determines whether to proceed to the product process based on the results determined in step S12. In step S12, when it is determined that the product process can be started, the process is proceeded to step S15. In step S15, the control device 90 controls the plasma processing apparatus 1 so as to execute the product process. In step S12, when it is determined that the product process cannot be started, the control device 90 returns the process to step S11. In this way, the control device 90 controls the plasma processing apparatus 1 so as to repeatedly execute the conditioning process without proceeding to the product process until it is determined that the product process can be started in step S12.

As described above, in the method of operating the plasma processing apparatus 1 according to the embodiment, first, the probe device 70 measures the data representing the state of plasma generated during the execution of at least one of the second film formation process or the seasoning process. Subsequently, the control device 90 determines whether the product process can be started based on the data measured by the probe device 70. In this case, it is possible to determine the stabilization of the surface inside the processing container 10 in a short time. Therefore, after the conditioning process is completed, it is possible to proceed to the product process in a short time without measuring the number of particles. In addition, by minimizing the number of particle measurements, it is possible to rapidly proceed to the product process.

For example, when measuring the number of particles, first, a substrate for a particle measurement is loaded into the processing container 10 of the plasma processing apparatus 1, and a plasma process for measuring the particles is performed. Subsequently, the substrate for the particle measurement is unloaded from the processing container 10, and the number of particles adhering to the substrate for the particle measurement is measured in a particle measurement apparatus provided separately from the plasma processing apparatus 1. Thereby, after the conditioning process is terminated, a time required to proceed to the product process becomes longer. Further, as the number of the particle measurement increases, the time required to proceed to the product process also becomes longer.

### Effects of Seasoning Process

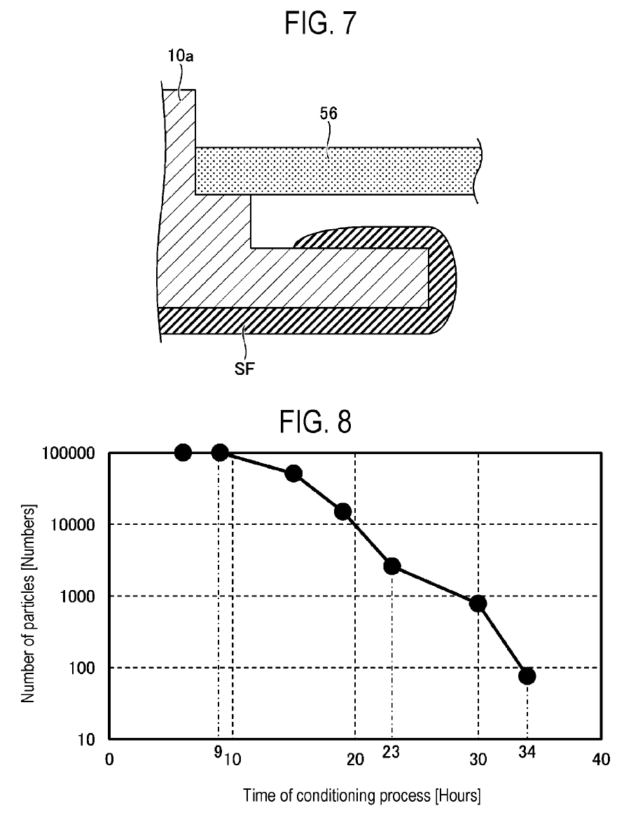

Effects of the seasoning process in the method of operating the plasma processing apparatus 1 according to an embodiment will now be described with reference to FIGS. 6 and 7. FIGS. 6 and 7 are enlarged views of a boundary portion between the ceiling plate 10a and the dielectric window 56 (region A2 in FIG. 1). FIG. 6 is a schematic cross-sectional view showing the ceiling plate 10a on which the seasoning process has not been performed. FIG. 7 is a schematic cross-sectional view showing the ceiling plate 10a on which the seasoning process has been performed.

As shown in FIG. 6, in the ceiling plate 10a on which the seasoning process has not been performed, there are cases in which a protrusion 10c caused by process variations is present. When the protrusion 10c is present in a narrow gap between the ceiling plate 10a and the dielectric window 56, there are cases in which the protrusion 10c is not covered with the thermal sprayed film SF and is thus exposed. In this case, it is considered that a discharge starting from the protrusion 10c occurs during the plasma processing, and particles caused by a metallic material such as aluminum are generated.

As shown in FIG. 7, when the seasoning process is performed inside the processing container 10, a surface of the ceiling plate 10a is flattened, and the protrusion 10c is eliminated. Therefore, the discharge starting from the protrusion 10c does not occur. Thereby, it is considered that it is possible to reduce the generation of the particles originating from the metallic material such as aluminum.

In the method of operating the plasma processing apparatus 1 according to the embodiment, the conditioning process may include both the seasoning process and the dummy process. In the seasoning process, the surface inside the processing container 10 is flattened. In the dummy process, radicals (e.g., fluorine radicals) in plasma generated from a halogen-containing gas during the cleaning process halogenate (e.g., fluorinate) a surface of the exposed portion inside the processing container 10, thereby stabilizing the surface inside the processing container 10. By combining these processes, it is possible to rapidly stabilize the surface inside the processing container 10. In addition, variations in the time required for the stabilization between the plasma processing apparatuses 1 can be reduced.

In the method of operating the plasma processing apparatus 1 according to the embodiment, the dummy process may be performed after the seasoning process. In this case, after reducing a surface area of the exposed portion inside the processing container 10, the surface of the exposed portion may be fluorinated.

In the method of operating the plasma processing apparatus 1 according to the embodiment, the dummy process may be performed first among the seasoning process and the dummy process. In this case, yttria constituting the thermal sprayed film SF reacts with the halogen-containing gas during the cleaning process of the dummy process, and a surface of the thermal sprayed film SF is covered with a passive film. Therefore, since the thermal sprayed film SF is protected by the passive film during the seasoning process, it is possible to reduce a damage to the thermal sprayed film SF.

In the method of operating the plasma processing apparatus 1 according to the embodiment, the dummy process may be performed last among the seasoning process and the dummy process. In this case, yttria constituting the thermal sprayed film SF reacts with the halogen-containing gas, and the surface of the thermal sprayed film SF is covered with the passive film. Therefore, since the thermal sprayed film SF is protected by the passive film while the product process is performed, it is possible to reduce a generation of particles caused by the thermal sprayed film SF.

While, in the above-described embodiment, the dummy process has been described as including the first film formation process, the second film formation process, and the cleaning process, the present disclosure is not limited thereto. For example, either the first film formation process or the second film formation process may be omitted.

### Experimental Results

Results of evaluating a relationship between time-series data of a current signal detected by the probe device 70 during an execution of the second film formation process and the number of particles adhering to the product substrate during the product process will now be described with reference to FIGS. 8 to 11.

FIG. 8 is a diagram showing a relationship between the time of the conditioning process and the number of the particles. In FIG. 8, the horizontal axis represents the time of the conditioning process [hours], and the vertical axis represents the number of the particles [numbers]. The time of the conditioning process is a total sum of the time of the dummy process in step S21, the time of the seasoning process in step S22, and the time of the dummy process in step S24. The number of the particles is the number of the particles adhering to a substrate when the substrate is processed under the same conditions as the product process.

As shown in FIG. 8, it can be seen that the number of the particles decreases as the time of the conditioning process elapses. For example, when the time of the conditioning process is 9 hours, 23 hours, and 34 hours, the number of the particles is approximately 100,000, 2,600, and 76, respectively.

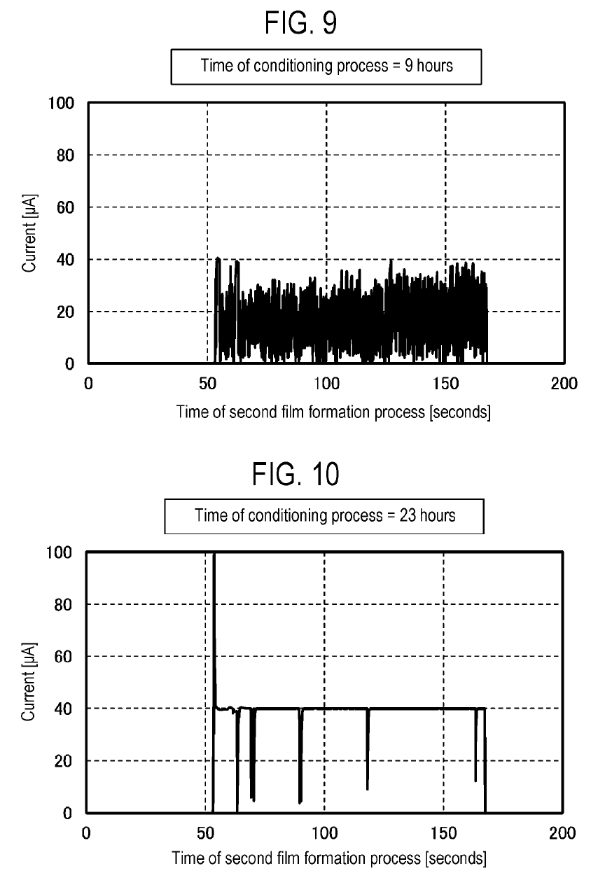

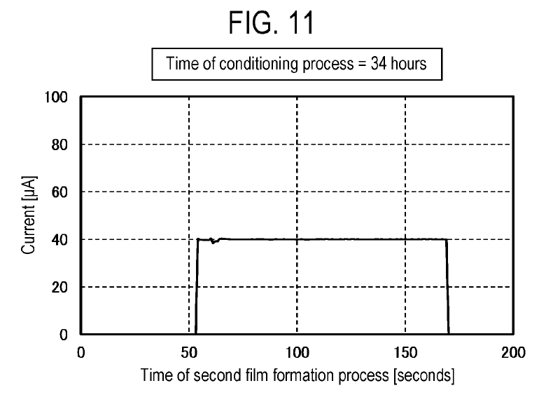

FIGS. 9 to 11 are diagrams showing variations in the current value detected by the probe device 70. FIG. 9 shows a result when the time of the conditioning process is 9 hours, FIG. 10 shows a result when the time of the conditioning process is 23 hours, and FIG. 11 shows a result when the time of the conditioning process is 34 hours. In FIGS. 9 to 11, the horizontal axis represents the time of the second film formation process [seconds], and the vertical axis represents the current value [μA] detected by the probe device 70.

As shown in FIGS. 9 to 11, variations in the current value detected by the probe device 70 decrease as the time of the conditioning process elapses.

Based on the result shown in FIG. 8 and the results shown in FIGS. 9 to 11 described above, it can be said that there is a correlation between the time-series data of the current signal detected by the probe device 70 during the execution of the second film formation process and the number of the particles adhering to the product substrate during the product process.

It should be noted that the embodiments disclosed herein are exemplary in all respects and are not restrictive. The embodiments described herein may be omitted, replaced, or modified in various forms without departing from the scope and spirit of the appended claims.

While, in the above embodiment, the case in which the film formed on the product substrate is the silicon nitride (SiN) film has been described, the present disclosure is not limited thereto. For example, the film formed on the product substrate may be an SiCN film, an SiOCN film, an SiON film, an SiO₂ film, or a silicon film. Further, while the case in which the microwaves are used as the plasma source has been described, the present disclosure is not limited thereto. Electromagnetic waves used as the plasma source may be in a frequency range capable of generating plasma.

According to the present disclosure in some embodiments, it is possible to rapidly determine the stabilization of the surface inside the processing container.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of operating a plasma processing apparatus, comprising:
executing a first plasma process which simulates a plasma processing of a product substrate;
executing a second plasma process with a higher electron temperature and a higher electron density than an electron temperature and an electron density in the first plasma process; and
measuring, by a probe device, data representing a state of plasma generated during the execution of at least one of the first plasma process or the second plasma process and determining whether the plasma processing of the product substrate can be started based on the measured data.

2. The method of claim 1, wherein the data is time-series data of a current signal detected by the probe device when an alternating current (AC) voltage is applied to the probe device.

3. The method of claim 2, wherein in the determining whether the product substrate can be started, whether the plasma processing of the product substrate can be started is determined based on a number of data values that fall outside a first range in a first period in the time-series data.

4. The method of claim 3, wherein the determining whether the product substrate can be started is executed after a component in contact with the plasma has been replaced and before the plasma processing of the product substrate is performed.

5. The method of claim 4, wherein the component is a ceiling plate of a processing container configured to accommodate the product substrate.

6. The method of claim 1, wherein the data includes first data measured while the first plasma process is executed.

7. The method of claim 1, wherein the data includes second data measured while the second plasma process is executed.

8. The method of claim 1, wherein the second plasma process includes generating plasma from a hydrogen-containing gas.

9. The method of claim 1, wherein the determining whether the product substrate can be started is executed after a component in contact with the plasma has been replaced and before the plasma processing of the product substrate is performed.

10. A plasma processing apparatus, comprising:
a processing container;
a gas supply configured to supply gas into the processing container;
a plasma source configured to introduce electromagnetic waves into the processing container; and
a controller,
wherein the controller is configured to control the gas supply and the plasma source to perform a process including:
executing a first plasma process which simulates a plasma processing of a product substrate;
executing a second plasma process with a higher electron temperature and a higher electron density than an electron temperature and an electron density in the first plasma process; and
measuring, by a probe device, data representing a state of plasma generated during the execution of at least one of the first plasma process or the second plasma process and determining whether the plasma processing of the product substrate can be started based on the measured data.
